(19) United States
(12) Patent Application Publication
(10) Pub. No.: US 2024/0258973 A1
(43) Pub. Date: Aug. 1, 2024

(54) TRACKER MODULE

(71) Applicant: Murata Manufacturing Co., Ltd., Nagaokakyo-shi (JP)

(72) Inventors: Takeshi KOGURE, Nagaokakyo-shi (JP); Takanori UEJIMA, Nagaokakyo-shi (JP); Masanari MIURA, Nagaokakyo-shi (JP)

(21) Appl. No.: 18/627,600

(22) Filed: Apr. 5, 2024

Related U.S. Application Data
(63) Continuation of application No. PCT/JP22/36657, filed on Sep. 30, 2022.

(30) Foreign Application Priority Data
Oct. 28, 2021 (JP) 2021-176551

(51) Int. Cl. H03F 1/02

(52) U.S. Cl. CPC H03F 1/0238; H03F 2200/102

(57) ABSTRACT

A tracker module is provide that includes an integrated circuit on a main surface of a module laminate, and at least one capacitor included in a switched-capacitor circuit disposed on the other main surface of the module laminate. The switched-capacitor circuit generates, based on an input voltage, a plurality of discrete voltages. The integrated circuit includes at least one switch included in the switched-capacitor circuit, and at least one switch included in a supply modulator that selectively outputs, based on an envelope signal, at least one of the plurality of discrete voltages. The at least one capacitor overlaps the integrated circuit in a plan view of the module laminate.

### CROSS REFERENCE TO RELATED APPLICATIONS

This application is a continuation of International Application No. PCT/JP2022/036657, filed Sep. 30, 2022, which claims priority to Japanese Patent Application No. 2021-176551, filed Oct. 28, 2021, the entire contents of each of which are hereby incorporated by reference in their entirety.

### TECHNICAL FIELD

The present disclosure relates to a tracker module.

### BACKGROUND

U.S. Pat. No. 9,755,672 (hereinafter “Patent Document 1”) discloses a power supply modulation circuit capable of supplying a power amplifier (PA) with a power supply voltage that is dynamically adjusted over time in accordance with a radio frequency (RF) signal.

In a tracker module equipped with the power supply modulation circuit (e.g., the power supply circuit) of Patent Document 1, a resistance loss and a parasitic capacitance in a wiring line of a switched-capacitor circuit may deteriorate the output characteristics of the power supply modulation circuit.

### SUMMARY OF THE INVENTION

In view of the foregoing, a tracker module is provided that reduces a resistance loss and a parasitic capacitance in a wiring line of a switched-capacitor circuit.

In an exemplary aspect, a tracker module is provided that includes a module laminate having a first main surface and a second main surface that oppose each other, at least one integrated circuit on the first main surface of the module laminate, and at least one capacitor included in a switched-capacitor circuit and that is on the second main surface of the module laminate. The switched-capacitor circuit is configured to generate, based on an input voltage, a plurality of discrete voltages. The at least one integrated circuit includes at least one switch included in the switched-capacitor circuit, and at least one switch included in a supply modulator configured to selectively output, based on an envelope signal, at least one of the plurality of discrete voltages. The at least one capacitor overlaps the at least one integrated circuit in a plan view of the module laminate.

In another exemplary aspect, a tracker module is provided that includes a module laminate having a first main surface and a second main surface that oppose to each other, at least one integrated circuit on the first main surface of the module laminate, and at least one capacitor included in a switched-capacitor circuit and that is on the second main surface of the module laminate. The switched-capacitor circuit is configured to generate, based on an input voltage, a plurality of discrete voltages. The at least one integrated circuit includes at least one switch included in the switched-capacitor circuit, and at least one switch included in a supply modulator that is connected to a digital control circuit and that is configured to selectively output at least one of a plurality of second voltages. The at least one capacitor overlaps the at least one integrated circuit in a plan view of the module laminate.

In yet another exemplary aspect, a tracker module is provided that includes a module laminate having a first main surface and a second main surface that oppose each other, at least one integrated circuit on the first main surface of the module laminate, and at least one capacitor included in a switched-capacitor circuit and that is on the second main surface of the module laminate. The at least one integrated circuit includes at least one switch included in the switched-capacitor circuit, and at least one switch included in a supply modulator. The at least one capacitor included in the switched-capacitor circuit includes a first capacitor having a first electrode and a second electrode, and a second capacitor having a third electrode and a fourth electrode. The at least one switch included in the switched-capacitor circuit includes a first switch, a second switch, a third switch, a fourth switch, a fifth switch, a sixth switch, a seventh switch, and an eighth switch. A first end of the first switch and a first end of the third switch are connected to the first electrode. A first end of the second switch and a first end of the fourth switch are connected to the second electrode. A first end of the fifth switch and a first end of the seventh switch are connected to the third electrode. A first end of the sixth switch and a first end of the eighth switch are connected to the fourth electrode. The second ends of the first switch, the second switch, the fifth switch, and the sixth switch are connected to each other. The second end of the third switch is connected to the second end of the seventh switch. The second end of the fourth switch is connected to the second end of the eighth switch. The supply modulator includes an output terminal. The at least one switch included in the supply modulator includes a ninth switch connected between the output terminal and each of the second ends of the first switch, the second switch, the fifth switch, and the sixth switch; and a tenth switch connected between the output terminal and each of the second ends the third switch and the seventh switch. The at least one capacitor overlaps the at least one integrated circuit in a plan view of the module laminate.

A tracker module according to the exemplary aspects of the present disclosure is configured to reduce a resistance loss and a parasitic capacitance in a wiring line of a switched-capacitor circuit.

### BRIEF DESCRIPTION OF DRAWINGS

FIG. 1 is a circuit configuration diagram of a communication device according to an exemplary embodiment.

FIG. 2A is a circuit configuration diagram of a pre-regulator circuit, a switched-capacitor circuit, a supply modulator, and a filter circuit according to the exemplary embodiment.

FIG. 2B is a circuit configuration diagram of a digital control circuit according to the exemplary embodiment.

FIG. 3A is a graph illustrating a power supply voltage supplied by digital envelope tracking.

FIG. 3B is a graph illustrating a power supply voltage supplied by analog envelope tracking.

FIG. 4 is a plan view of a tracker module according to a first exemplary aspect.

FIG. 5 is a plan view of the tracker module according to the first exemplary aspect.

FIG. 6 is a sectional view of the tracker module according to the first exemplary aspect.

FIG. 7 is a plan view of a tracker module according to a second exemplary aspect.

FIG. 8 is a plan view of the tracker module according to the second exemplary aspect.

FIG. 9 is a sectional view of the tracker module according to the second exemplary aspect.

FIG. 10 is a sectional view of a tracker module according to a modification of the second exemplary aspect.

### DETAILED DESCRIPTION

Hereinafter, exemplary embodiments of the present disclosure will be described in detail with reference to the drawings. The embodiments described below each illustrate a general or specific example. The numerical values, shapes, materials, constituent elements, the arrangement and connection manner of the constituent elements, and so forth described in the following embodiments are merely examples and are not intended to limit the present invention.

The drawings are schematic diagrams drawn with emphasis, omission, or ratio adjustment performed as appropriate in order to illustrate the exemplary aspects of the present disclosure. The illustration therein is not necessarily strict, and may be different from actual shapes, positional relationships, and ratios. In the drawings, constituent elements that are substantially the same are denoted by the same reference numerals, and a repeated description thereof may be omitted or simplified.

In the drawings referred to below, an x-axis and a y-axis are axes orthogonal to each other on a plane parallel to main surfaces of a module laminate. Specifically, when the module laminate has a rectangular shape in a plan view, the x-axis is parallel to a first side of the module laminate, and the y-axis is parallel to a second side orthogonal to the first side of the module laminate. A z-axis is an axis perpendicular to the main surfaces of the module laminate. The positive direction thereof indicates an upward direction, and the negative direction thereof indicates a downward direction.

In the circuit configurations of the present disclosure, the term “connected” includes not only a direct connection using a connection terminal and/or a wiring conductor, but also an electrical connection via another circuit element. Moreover, the phrase “connected between A and B” means connected to both A and B between A and B and includes being connected in series to a path connecting A and B and being connected in parallel (e.g., in shunt) between the path and ground.

Regarding the disposition of components in the present disclosure, the phrase “a component is disposed on or in a laminate” includes that the component is disposed on a main surface of the laminate and that the component is disposed in the laminate. Moreover, the phrase “a component is disposed on a main surface of a laminate” includes not only that the component is disposed in contact with the main surface of the laminate but also that the component is disposed above the main surface without being in contact with the main surface (for example, the component is stacked on another component disposed in contact with the main surface). The phrase “a component is disposed on a main surface of a laminate” may include that the component is disposed in a recessed portion formed on the main surface. Moreover, the phrase “a component is disposed in a laminate” includes not only that the component is encapsulated in the module laminate but also that the entire component is disposed between both main surfaces of the laminate but a part of the component is not covered with the laminate and that only a part of the component is disposed in the laminate.

According to an exemplary aspect regarding the disposition of components, the phrase “in a plan view of a module laminate” means that an object is viewed by orthographic projection on an xy plane from a z-axis positive side. Moreover, the phrase “A overlaps B in a plan view” means that at least a part of the region of A orthographically projected on the xy plane overlaps at least a part of the region of B orthographically projected on the xy plane. Conversely, the phrase “A does not overlap B in a plan view” means that the region of A orthographically projected on the xy plane does not overlap any region of B orthographically projected on the xy plane.

Regarding the disposition of components in the present disclosure, the phrase “C is disposed closer to A than B” means that the distance between A and C is shorter than the distance between A and B. Here, the “distance between A and B” means the shortest distance between A and B. That is, the “distance between A and B” means the length of the shortest line segment among a plurality of line segments connecting certain points on the surface of A and certain points on the surface of B.

### EXEMPLARY EMBODIMENT

Hereinafter, a tracker module and a communication device according to an exemplary embodiment will be described with reference to the drawings.

### [1. Circuit Configurations of Communication Device 7 and Power Supply Circuit 1]

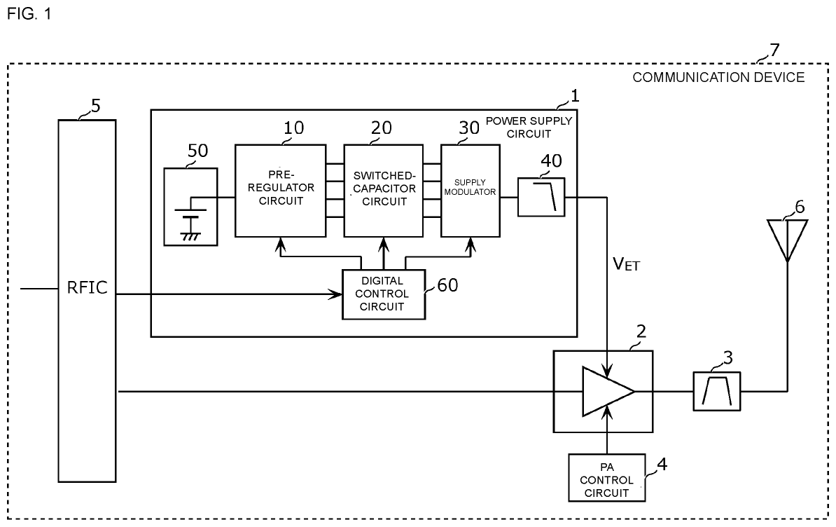

The circuit configuration of a communication device 7 according to the present embodiment will be described with reference to FIG. 1. FIG. 1 is a circuit configuration diagram of the communication device 7 according to the exemplary embodiment.

### [1.1. Circuit Configuration of Communication Device 7]

First, the circuit configuration of the communication device 7 will be described. As illustrated in FIG. 1, the communication device 7 according to the present embodiment includes a power supply circuit 1, a power amplifier (PA) 2, a filter 3, a PA control circuit 4, a radio frequency integrated circuit (RFIC) 5, and an antenna 6.

The power supply circuit 1 is configured to supply a power supply voltage V_{ET} to the PA 2 in a digital envelope tracking (ET) mode. In the digital V_{ET} mode, the voltage level of the power supply voltage V_{ET} is selected from among a plurality of discrete voltage levels based on a digital control signal corresponding to an envelope signal, and changes with time.

The envelope signal is a signal indicating the envelope value of a modulated signal (RF signal). An envelope value is represented by, for example, the square root of (I²+Q²). (I, Q) represents a constellation point herein. The constellation point is a point representing, on a constellation diagram, a signal modulated by digital modulation. The details of the digital ET mode will be described below with reference to FIG. 3A and FIG. 3B.

Although the power supply circuit 1 supplies one power supply voltage V_{ET} to the one PA 2 in FIG. 1, the power supply circuit 1 may supply the same power supply voltage V_{ET} to a plurality of PAs. The power supply circuit 1 can be configured to supply different power supply voltages to a plurality of PAs.

As illustrated in FIG. 1, the power supply circuit 1 includes a pre-regulator circuit 10, a switched-capacitor circuit 20, a supply modulator 30, a filter circuit 40, a direct current (DC) power source 50, and a digital control circuit 60.

The pre-regulator circuit 10 includes a power inductor and a switch. The power inductor is an inductor used to raise and/or lower a DC voltage. The power inductor is disposed in series with a signal path. Alternatively, the power inductor may be connected between the signal path and ground (disposed in parallel). The pre-regulator circuit 10 can be configured to convert an input voltage into a first voltage by using the power inductor. Such a pre-regulator circuit 10 may also be referred to as a magnetic regulator or a DC-DC converter.

According to an exemplary aspect, it is noted that the pre-regulator circuit 10 does not include the power inductor, and can be, for example, a circuit or the like that raises a voltage by switching between capacitors respectively disposed in a series arm path and a parallel arm path of the pre-regulator circuit 10. The pre-regulator circuit 10 may further include a transformer in an exemplary aspect.

The switched-capacitor circuit 20 includes a plurality of capacitors and a plurality of switches, and is configured to generate, from the first voltage received from the pre-regulator circuit 10, a plurality of second voltages as a plurality of discrete voltages each having a corresponding one of a plurality of discrete voltage levels. The switched-capacitor circuit 20 may also be referred to as a switched-capacitor voltage balancer.

The supply modulator 30 can be configured to select at least one of the plurality of second voltages generated by the switched-capacitor circuit 20 and outputting the selected voltage to the filter circuit 40, based on a digital control signal corresponding to an envelope signal.

The filter circuit 40 can be configured to filter a signal (e.g., a second voltage) received from the supply modulator 30. Moreover, the filter circuit 40 includes, for example, a low pass filter (LPF).

The DC power source 50 can be configured to supply a DC voltage to the pre-regulator circuit 10. It is noted that the DC power source 50 may be, but is not limited to, a rechargeable battery, for example.

The digital control circuit 60 can be configured to control, based on a digital control signal from the RFIC 5, the pre-regulator circuit 10, the switched-capacitor circuit 20, and the supply modulator 30.

It is noted that the power supply circuit 1 may not include at least one of the pre-regulator circuit 10, the switched-capacitor circuit 20, the supply modulator 30, the filter circuit 40, the DC power source 50, and the digital control circuit 60. For example, the power supply circuit 1 may not include the pre-regulator circuit 10, the filter circuit 40, or the DC power source 50 in exemplary aspects. Instead, any combination of the pre-regulator circuit 10, the switched-capacitor circuit 20, the supply modulator 30, and the filter circuit 40 may be integrated into a single circuit.

The PA 2 is connected between the RFIC 5 and the filter 3. The PA 2 is configured to receive the power supply voltage V_{ET} from the power supply circuit 1 and receiving a bias signal from the PA control circuit 4. Accordingly, the PA 2 is configured to amplify a transmission signal of a predetermined band received from the RFIC 5.

The filter 3 is connected between the PA 2 and the antenna 6. The filter 3 has a passband including the predetermined band. Accordingly, the filter 3 is configured to pass the transmission signal of the predetermined band amplified by the PA 2.

The PA control circuit 4 is configured to control the PA 2. Specifically, the PA control circuit 4 is configured to supply a bias signal to the PA 2.

The RFIC 5 is an example of a control circuit and is an example of a signal processing circuit that processes an RF signal. Specifically, the RFIC 5 performs signal processing such as up-conversion on a transmission signal input thereto and supplies an RF transmission signal generated through the signal processing to the PA 2. The RFIC 5 includes a control unit that controls the power supply circuit 1. Some or all of the functions of the control unit of the RFIC 5 may be implemented outside the RFIC 5.

The antenna 6 transmits the signal of the predetermined band input from the PA 2 through the filter 3.

The predetermined band is a frequency band for a communication system constructed using the radio access technology (RAT). The predetermined band is defined in advance by a standardizing body (for example, 3rd Generation Partnership Project (3GPP, registered trademark), Institute of Electrical and Electronics Engineers (IEEE), or the like). Examples of the communication system include a 5th Generation New Radio (5G NR) system, a Long Term Evolution (LTE) system, and a Wireless Local Area Network (WLAN) system.

It should be appreciated that the circuit configuration of the communication device 7 illustrated in FIG. 1 is illustrative and is not restrictive. For example, the communication device 7 may not include the antenna 6. For example, the communication device 7 may include a plurality of antennas in an alternative aspect.

### [1.2. Circuit Configuration of Power Supply Circuit 1]

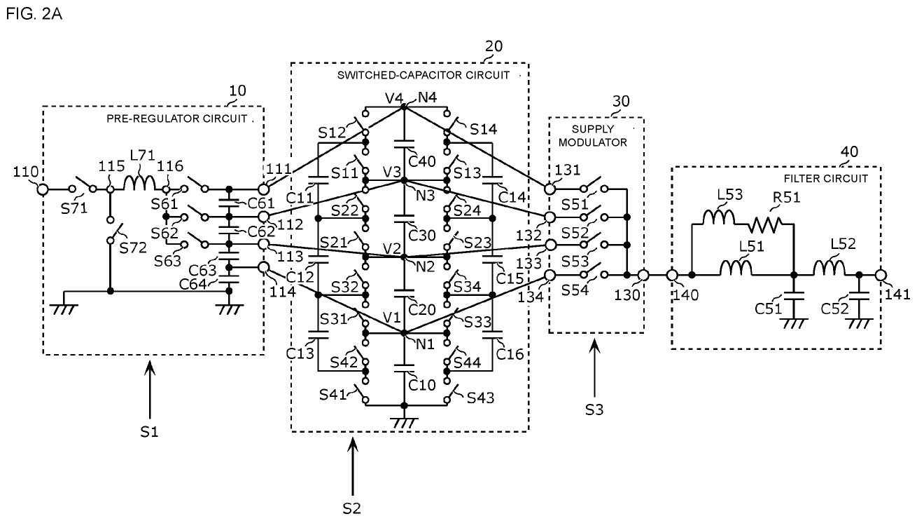

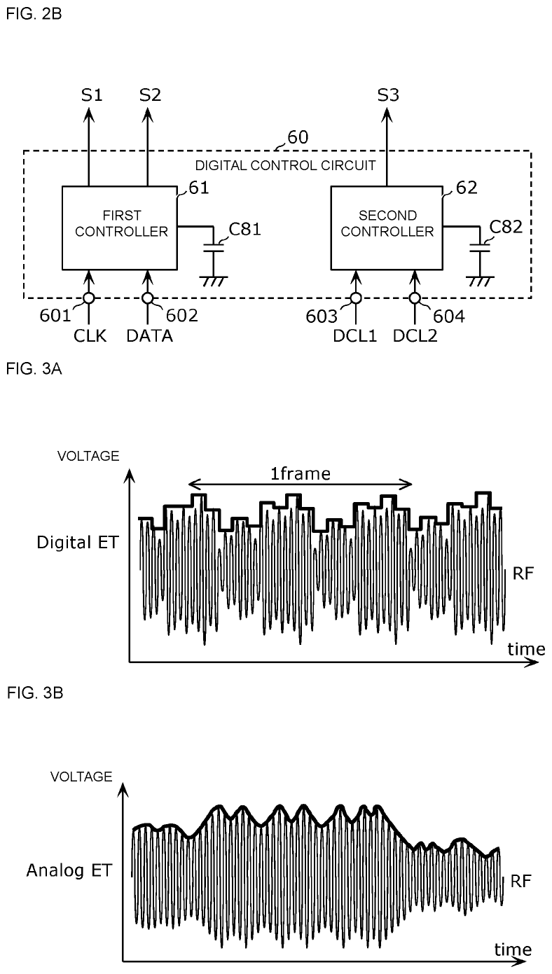

Next, the circuit configurations of the pre-regulator circuit 10, the switched-capacitor circuit 20, the supply modulator 30, the filter circuit 40, and the digital control circuit 60 included in the power supply circuit 1 will be described with reference to FIG. 2A and FIG. 2B. FIG. 2A is a circuit configuration diagram of the pre-regulator circuit 10, the switched-capacitor circuit 20, the supply modulator 30, and the filter circuit 40 according to the present embodiment. FIG. 2B is a circuit configuration diagram of the digital control circuit 60 according to the present embodiment.

FIG. 2A illustrates an exemplary circuit configuration. The pre-regulator circuit 10, the switched-capacitor circuit 20, the supply modulator 30, the filter circuit 40, and the digital control circuit 60 may be packaged by using any of a wide variety of circuit packaging methods and circuit techniques. Thus, the description of the individual circuits provided below are exemplary.

### [1.2.1. Circuit Configuration of Switched-Capacitor Circuit 20]

First, the circuit configuration of the switched-capacitor circuit 20 will be described. As illustrated in FIG. 2A, the switched-capacitor circuit 20 includes capacitors C11 to C16, capacitors C10, C20, C30, and C40, and switches S11 to S14, S21 to S24, S31 to S34, and S41 to S44. Energy and electric charge are input from the pre-regulator circuit 10 to the switched-capacitor circuit 20 at nodes N1 to N4 and output from the switched-capacitor circuit 20 to the supply modulator 30 at the nodes N1 to N4.

The capacitors C11 to C16 each function as a flying capacitor (also referred to as a transfer capacitor). Specifically, the capacitors C11 to C16 are each used to raise or lower the first voltage supplied from the pre-regulator circuit 10. More specifically, the capacitors C11 to C16 cause electric charges to move between the capacitors C11 to C16 and the nodes N1 to N4 so that voltages V1 to V4 (voltages with respect to a ground potential) satisfying V1:V2:V3:V4=1:2:3:4 are maintained at the four nodes N1 to N4. The voltages V1 to V4 correspond to a plurality of second voltages each having a corresponding one of a plurality of discrete voltage levels.

The capacitor C11 is an example of a first capacitor and a first flying capacitor. The capacitor C11 has two electrodes (an example of a first electrode and a second electrode). One of the two electrodes of the capacitor C11 is connected to one terminal of the switch S11 and one terminal of the switch S12. The other of the two electrodes of the capacitor C11 is connected to one terminal of the switch S21 and one terminal of the switch S22. For purposes of this disclosure the term “one terminal” may generally be considered a “first end” and the term “another terminal” or the “other terminal” may generally be considered a “second end”. These terms for such components may be interchangeable as would be appreciated to one skilled in the art.

The capacitor C12 has two electrodes. One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

The capacitor C13 is an example of a third flying capacitor and has two electrodes. One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

The capacitor C14 is an example of a second capacitor and a second flying capacitor and has two electrodes (an example of a third electrode and a fourth electrode). One of the two electrodes of the capacitor C14 is connected to one terminal of the switch S13 and one terminal of the switch S14. The other of the two electrodes of the capacitor C14 is connected to one terminal of the switch S23 and one terminal of the switch S24.

The capacitor C15 has two electrodes. One of the two electrodes of the capacitor C15 is connected to the one terminal of the switch S23 and the one terminal of the switch S24. The other of the two electrodes of the capacitor C15 is connected to one terminal of the switch S33 and one terminal of the switch S34.

The capacitor C16 is an example of a fourth flying capacitor and has two electrodes. One of the two electrodes of the capacitor C16 is connected to the one terminal of the switch S33 and the one terminal of the switch S34. The other of the two electrodes of the capacitor C16 is connected to one terminal of the switch S43 and one terminal of the switch S44.

A set of the capacitors C11 and C14, a set of the capacitors C12 and C15, and a set of the capacitors C13 and C16 can each be charged and discharged in a complementary manner as a result of a first phase and a second phase being repeated.

Specifically, in the first phase, the switches S12, S13, S22, S23, S32, S33, S42, and S43 are turned ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

As a result of the first phase and the second phase being repeated, for example, when one of the capacitors C12 and C15 is charged through the node N2, the other of the capacitors C12 and C15 can be discharged to the capacitor C30. In short, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner as a result of the first phase and the second phase being repeated.

The capacitors C10, C20, C30, and C40 each function as a smoothing capacitor. Specifically, the capacitors C10, C20, C30, and C40 are used to hold and smooth the voltages V1 to V4 at the nodes N1 to N4, respectively.

The capacitor C10 is connected between the node N1 and ground. Specifically, one of the two electrodes of the capacitor C10 is connected to the node N1. On the other hand, the other of the two electrodes of the capacitor C10 is connected to ground.

The capacitor C20 is connected between the nodes N2 and N1. Specifically, one of the two electrodes of the capacitor C20 is connected to the node N2. On the other hand, the other of the two electrodes of the capacitor C20 is connected to the node N1.

The capacitor C30 is connected between the nodes N3 and N2. Specifically, one of the two electrodes of the capacitor C30 is connected to the node N3. On the other hand, the other of the two electrodes of the capacitor C30 is connected to the node N2.

The capacitor C40 is connected between the nodes N4 and N3. Specifically, one of the two electrodes of the capacitor C40 is connected to the node N4. On the other hand, the other of the two electrodes of the capacitor C40 is connected to the node N3.

The switch S11 is an example of a first switch and is connected between the one of the two electrodes of the capacitor C11 and the node N3. Specifically, the one terminal of the switch S11 is connected to the one of the two electrodes of the capacitor C11. On the other hand, the other terminal of the switch S11 is connected to the node N3.

The switch S12 is an example of a third switch and is connected between the one of the two electrodes of the capacitor C11 and the node N4. Specifically, the one terminal of the switch S12 is connected to the one of the two electrodes of the capacitor C11. On the other hand, the other terminal of the switch S12 is connected to the node N4.

The switch S21 is an example of a fourth switch and is connected between the one of the two electrodes of the capacitor C12 and the node N2. Specifically, the one terminal of the switch S21 is connected to the one of the two electrodes of the capacitor C12 and the other of the two electrodes of the capacitor C11. On the other hand, the other terminal of the switch S21 is connected to the node N2.

The switch S22 is an example of a second switch and is connected between the one of the two electrodes of the capacitor C12 and the node N3. Specifically, the one terminal of the switch S22 is connected to the one of the two electrodes of the capacitor C12 and the other of the two electrodes of the capacitor C11. On the other hand, the other terminal of the switch S22 is connected to the node N3.

The switch S31 is connected between the other of the two electrodes of the capacitor C12 and the node N1. Specifically, the one terminal of the switch S31 is connected to the other of the two electrodes of the capacitor C12 and the one of the two electrodes of the capacitor C13. On the other hand, the other terminal of the switch S31 is connected to the node N1.

The switch S32 is connected between the other of the two electrodes of the capacitor C12 and the node N2. Specifically, the one terminal of the switch S32 is connected to the other of the two electrodes of the capacitor C12 and the one of the two electrodes of the capacitor C13. On the other hand, the other terminal of the switch S32 is connected to the node N2. That is, the other terminal of the switch S32 is connected to the other terminal of the switch S21.

The switch S41 is connected between the other of the two electrodes of the capacitor C13 and ground. Specifically, the one terminal of the switch S41 is connected to the other of the two electrodes of the capacitor C13. On the other hand, the other terminal of the switch S41 is connected to ground.

The switch S42 is connected between the other of the two electrodes of the capacitor C13 and the node N1. Specifically, the one terminal of the switch S42 is connected to the other of the two electrodes of the capacitor C13. On the other hand, the other terminal of the switch S42 is connected to the node N1. That is, the other terminal of the switch S42 is connected to the other terminal of the switch S31.

The switch S13 is an example of a fifth switch and is connected between the one of the two electrodes of the capacitor C14 and the node N3. Specifically, the one terminal of the switch S13 is connected to the one of the two electrodes of the capacitor C14. On the other hand, the other terminal of the switch S13 is connected to the node N3. That is, the other terminal of the switch S13 is connected to the other terminal of the switch S11 and the other terminal of the switch S22.

The switch S14 is an example of a seventh switch and is connected between the one of the two electrodes of the capacitor C14 and the node N4. Specifically, the one terminal of the switch S14 is connected to the one of the two electrodes of the capacitor C14. On the other hand, the other terminal of the switch S14 is connected to the node N4. That is, the other terminal of the switch S14 is connected to the other terminal of the switch S12.

The switch S23 is an example of an eighth switch and is connected between the one of the two electrodes of the capacitor C15 and the node N2. Specifically, the one terminal of the switch S23 is connected to the one of the two electrodes of the capacitor C15 and the other of the two electrodes of the capacitor C14. On the other hand, the other terminal of the switch S23 is connected to the node N2. That is, the other terminal of the switch S23 is connected to the other terminal of the switch S21 and the other terminal of the switch S32.

The switch S24 is an example of a sixth switch and is connected between the one of the two electrodes of the capacitor C15 and the node N3. Specifically, the one terminal of the switch S24 is connected to the one of the two electrodes of the capacitor C15 and the other of the two electrodes of the capacitor C14. On the other hand, the other terminal of the switch S24 is connected to the node N3. That is, the other terminal of the switch S24 is connected to the other terminal of the switch S11, the other terminal of the switch S22, and the other terminal of the switch S13.

The switch S33 is connected between the other of the two electrodes of the capacitor C15 and the node N1. Specifically, the one terminal of the switch S33 is connected to the other of the two electrodes of the capacitor C15 and the one of the two electrodes of the capacitor C16. On the other hand, the other terminal of the switch S33 is connected to the node N1. That is, the other terminal of the switch S33 is connected to the other terminal of the switch S31 and the other terminal of the switch S42.

The switch S34 is connected between the other of the two electrodes of the capacitor C15 and the node N2. Specifically, the one terminal of the switch S34 is connected to the other of the two electrodes of the capacitor C15 and the one of the two electrodes of the capacitor C16. On the other hand, the other terminal of the switch S34 is connected to the node N2. That is, the other terminal of the switch S34 is connected to the other terminal of the switch S21, the other terminal of the switch S32, and the other terminal of the switch S23.

The switch S43 is connected between the other of the two electrodes of the capacitor C16 and ground. Specifically, the one terminal of the switch S43 is connected to the other of the two electrodes of the capacitor C16. On the other hand, the other terminal of the switch S43 is connected to ground.

The switch S44 is connected between the other of the two electrodes of the capacitor C16 and the node N1. Specifically, the one terminal of the switch S44 is connected to the other of the two electrodes of the capacitor C16. On the other hand, the other terminal of the switch S44 is connected to the node N1. That is, the other terminal of the switch S44 is connected to the other terminal of the switch S31, the other terminal of the switch S42, and the other terminal of the switch S33.

A first set of switches including the switches S12, S13, S22, S23, S32, S33, S42, and S43, and a second set of switches including the switches S11, S14, S21, S24, S31, S34, S41, and S44 are turned ON and OFF in a complementary manner. Specifically, in the first phase, the switches in the first set are turned ON whereas the switches in the second set are turned OFF. Conversely, in the second phase, the switches in the first set are turned OFF whereas the switches in the second set are turned ON.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. In other words, because the capacitors C10 to C40 are constantly charged by the capacitors C11 to C13 or the capacitors C14 to C16, the nodes N1 to N4 are rapidly replenished with electric charges even when currents rapidly flow from the nodes N1 to N4 to the supply modulator 30. Thus, potential variations at the nodes N1 to N4 can be reduced in this configuration.

As a result of operating in the above-described manner, the switched-capacitor circuit 20 is configured to maintain substantially equal voltages across each of the capacitors C10, C20, C30, and C40. Specifically, the voltages V1 to V4 (voltages with respect to a ground potential) satisfying V1:V2:V3:V4=1:2:3:4 are maintained at the four nodes labeled V1 to V4. The levels of the voltages V1 to V4 correspond to a plurality of discrete voltage levels that can be supplied to the supply modulator 30 by the switched-capacitor circuit 20.

It should be appreciated that the voltage ratio V1:V2:V3:V4 is not limited to 1:2:3:4. For example, the voltage ratio V1:V2:V3:V4 may be 1:2:4:8 in an alternative exemplary aspect.

It should be appreciated that the configuration of the switched-capacitor circuit 20 illustrated in FIG. 2A is illustrative and is not restrictive. In FIG. 2A, the switched-capacitor circuit 20 is configured to supply voltages of four discrete voltage levels, but the configuration is not limited thereto. Moreover, in an exemplary aspect, the switched-capacitor circuit 20 can be configured to supply voltages of any number of two or more discrete voltage levels. For example, when supplying voltages of two discrete voltage levels, it is sufficient that the switched-capacitor circuit 20 include at least the capacitors C11, C14, and C30 and the switches S11 to S14 and S21 to S24.

### [1.2.2. Circuit Configuration of Supply Modulator 30]

Next, the circuit configuration of the supply modulator 30 will be described. The supply modulator 30 is connected to the digital control circuit 60, and includes input terminals 131 to 134, switches S51 to S54, and an output terminal 130, as illustrated in FIG. 2A.

The output terminal 130 is connected to the filter circuit 40. The output terminal 130 is a terminal for supplying the filter circuit 40 with a voltage selected from among the voltages V1 to V4.

The input terminals 131 to 134 are connected to the nodes N4 to N1 of the switched-capacitor circuit 20, respectively. The input terminals 131 to 134 are terminals for receiving the voltages V4 to V1 from the switched-capacitor circuit 20, respectively.

The switch S51 is an example of a tenth switch and is connected between the input terminal 131 and the output terminal 130. Specifically, the switch S51 has a terminal connected to the input terminal 131 and a terminal connected to the output terminal 130. In this connection configuration, ON/OFF switching of the switch S51 by a control signal S3 enables switching between connection and disconnection between the input terminal 131 and the output terminal 130.

The switch S52 is an example of a ninth switch and is connected between the input terminal 132 and the output terminal 130. Specifically, the switch S52 has a terminal connected to the input terminal 132 and a terminal connected to the output terminal 130. In this connection configuration, ON/OFF switching of the switch S52 by the control signal S3 enables switching between connection and disconnection between the input terminal 132 and the output terminal 130.

The switch S53 is connected between the input terminal 133 and the output terminal 130. Specifically, the switch S53 has a terminal connected to the input terminal 133 and a terminal connected to the output terminal 130. In this connection configuration, ON/OFF switching of the switch S53 by the control signal S3 enables switching between connection and disconnection between the input terminal 133 and the output terminal 130.

The switch S54 is connected between the input terminal 134 and the output terminal 130. Specifically, the switch S54 has a terminal connected to the input terminal 134 and a terminal connected to the output terminal 130. In this connection configuration, ON/OFF switching of the switch S54 by the control signal S3 enables switching between connection and disconnection between the input terminal 134 and the output terminal 130.

In operation, these switches S51 to S54 are controlled so as to be exclusively turned ON. In other words, only any one of the switches S51 to S54 is turned ON, and the others are turned OFF. Accordingly, the supply modulator 30 is configured to output one voltage selected from among the voltages V1 to V4.

It should be appreciated that the configuration of the supply modulator 30 illustrated in FIG. 2A is illustrative and is not restrictive. For example, the switches S51 to S54 can have any configuration as long as at least one of the four input terminals 131 to 134 can be selectively connected to the output terminal 130. For example, the supply modulator 30 may further include a switch connected between a set of the switches S51 to S53 and a set of the switch S54 and the output terminal 130. For example, the supply modulator 30 may further include a switch connected between a set of the switches S51 and S52 and a set of the switches S53 and S54 and the output terminal 130.

The supply modulator 30 can be configured to output two or more voltages. In this case, the supply modulator 30 may further include a necessary number of additional switch sets having the same configuration as the set of the switches S51 to S54 and additional output terminals.

In a case where voltages of two discrete voltage levels are supplied from the switched-capacitor circuit 20, it is sufficient that the supply modulator 30 include at least the switches S51 and S52.

### [1.2.3. Circuit Configuration of Pre-Regulator Circuit 10]

The configuration of the pre-regulator circuit 10 will be described. As illustrated in FIG. 2A, the pre-regulator circuit 10 includes an input terminal 110, output terminals 111 to 114, inductor connection terminals 115 and 116, switches S61 to S63, S71, and S72, a power inductor L71, and capacitors C61 to C64.

The input terminal 110 is an input terminal for a DC voltage. Specifically, the input terminal 110 is a terminal for receiving an input voltage from the DC power source 50.

The output terminal 111 is an output terminal for the voltage V4. Specifically, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. Specifically, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. Specifically, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. Specifically, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110 and the one end of the power inductor L71. Specifically, the switch S71 has a terminal connected to the input terminal 110, and a terminal connected to the one end of the power inductor L71 via the inductor connection terminal 115. In this connection configuration, ON/OFF switching of the switch S71 enables switching between connection and disconnection between the input terminal 110 and the one end of the power inductor L71.

The switch S72 is connected between the one end of the power inductor L71 and ground. Specifically, the switch S72 has a terminal connected to the one end of the power inductor L71 via the inductor connection terminal 115, and a terminal connected to ground. In this connection configuration, ON/OFF switching of the switch S72 enables switching between connection and disconnection between the one end of the power inductor L71 and ground.

The switch S61 is connected between the other end of the power inductor L71 and the output terminal 111. Specifically, the switch S61 has a terminal connected to the other end of power inductor L71, and a terminal connected to the output terminal 111. In this connection configuration, ON/OFF switching of the switch S61 enables switching between connection and disconnection between the other end of the power inductor L71 and the output terminal 111.

The switch S62 is connected between the other end of the power inductor L71 and the output terminal 112. Specifically, the switch S62 has a terminal connected to the other end of power inductor L71, and a terminal connected to the output terminal 112. In this connection configuration, ON/OFF switching of the switch S62 enables switching between connection and disconnection between the other end of the power inductor L71 and the output terminal 112.

The switch S63 is connected between the other end of the power inductor L71 and the output terminal 113. Specifically, the switch S63 has a terminal connected to the other end of power inductor L71, and a terminal connected to the output terminal 113. In this connection configuration, ON/OFF switching of the switch S63 enables switching between connection and disconnection between the other end of the power inductor L71 and the output terminal 113.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

The one of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled so as to be exclusively turned ON. In other words, only any one of the switches S61 to S63 is turned ON, and the others are turned OFF. Turning ON of any one of the switches S61 to S63 enables the pre-regulator circuit 10 to change the voltage to be supplied to the switched-capacitor circuit 20 at the voltage levels of the voltages V2 to V4.

The pre-regulator circuit 10 configured as described above supplies electric charge to the switched-capacitor circuit 20 via at least one of the output terminals 111 to 113.

When an input voltage is converted into one first voltage, it is sufficient that the pre-regulator circuit 10 include at least the switches S71 and S72 and the power inductor L71 according to an exemplary aspect.

### [1.2.4. Circuit Configuration of Filter Circuit 40]

Next, the circuit configuration of the filter circuit 40 will be described. As illustrated in FIG. 2A, the filter circuit 40 is a resistor-inductor-capacitor (RLC) circuit, and includes inductors L51 to L53, capacitors C51 and C52, a resistor R51, an input terminal 140, and an output terminal 141.

The input terminal 140 is an input terminal for a voltage selected by the supply modulator 30. Specifically, the input terminal 140 is a terminal for receiving a voltage selected from among the plurality of voltages V1 to V4.

The output terminal 141 is an output terminal for the power supply voltage V_{ET}. Specifically, the output terminal 141 is a terminal for supplying the power supply voltage V_{ET} to the PA 2.

The inductors L51 to L53, the capacitors C51 and C52, and the resistor R51 form a low pass filter in the exemplary aspect. Accordingly, the filter circuit 40 is configured to reduce RF components included in the power supply voltage. For example, when the predetermined band is a frequency band for frequency division duplex (FDD), the filter circuit 40 is configured to reduce frequency components of a gap between an uplink operating band and a downlink operating band of the predetermined band.

It should be appreciated that the configuration of the filter circuit 40 illustrated in FIG. 2A is illustrative and is not restrictive. For example, the filter circuit 40 may not include the inductor L53 or the resistor R51. Instead, the filter circuit 40 may include an inductor connected to one of the two electrodes of the capacitor C51 and an inductor connected to one of the two electrodes of the capacitor C52 in an alterative aspect.

### [1.2.5. Circuit Configuration of Digital Control Circuit 60]

Next, the circuit configuration of the digital control circuit 60 will be described. As illustrated in FIG. 2B, the digital control circuit 60 includes a first controller 61, a second controller 62, capacitors C81 and C82, and control terminals 601 to 604.

The first controller 61 is configured to process source-synchronous digital control signals to generate control signals S1 and S2. The control signal S1 is a signal for controlling ON/OFF of the switches S61 to S63, S71, and S72 included in the pre-regulator circuit 10. The control signal S2 is a signal for controlling ON/OFF of the switches S11 to S14, S21 to S24, S31 to S34, and S41 to S44 included in the switched-capacitor circuit 20.

It is noted that the digital control signals processed by the first controller 61 are not limited to source-synchronous digital control signals. For example, the first controller 61 may process clock-embedded digital control signals in an alternative aspect.

In the present embodiment, one set of a clock signal and a data signal is used as digital control signals for the pre-regulator circuit 10 and the switched-capacitor circuit 20, but the digital control signals are not limited thereto. For example, sets of a clock signal and a data signal can be individually used as digital control signals for the pre-regulator circuit 10 and the switched-capacitor circuit 20 in an alternative aspect.

The second controller 62 processes digitally controlled level (DCL) signals (DCL1 and DCL2) received from the RFIC 5 via the control terminals 603 and 604 to generate a control signal S3. The DCL signals (DCL1 and DCL2) correspond to a first envelope signal. The control signal S3 is a signal for controlling ON/OFF of the switches S51 to S54 included in the supply modulator 30.

The DCL signals (DCL1 and DCL2) are each a 1-bit signal. The voltages V1 to V4 are each represented by a combination of two 1-bit signals. For example, V1, V2, V3, and V4 are represented by “00”, “01”, “10”, and “11”, respectively. A gray code may be used to express a voltage level.

The capacitor C81 is connected between the first controller 61 and ground. For example, the capacitor C81 is connected between ground and a power supply line that supplies power to the first controller 61, and functions as a bypass capacitor. The capacitor C82 is connected between the second controller 62 and ground.

In the present embodiment, two DCL signals are used to control the supply modulator 30, but the number of DCL signals is not limited thereto. For example, one or any number of three or more DCL signals may be used in accordance with the number of voltage levels selectable by the supply modulator 30 in an alternative aspect. Moreover, the digital control signal used to control the supply modulator 30 is not limited to a DCL signal as would be appreciated to one skilled in the art.

### [2. Description of Digital ET Mode]

It is noted that the digital ET mode will be described with reference to FIG. 3A and FIG. 3B in comparison with an existing ET mode (hereinafter referred to as an analog ET mode). FIG. 3A is a graph illustrating an example of transition of a power supply voltage in the digital ET mode. FIG. 3B is a graph illustrating an example of transition of a power supply voltage in the analog ET mode. In FIG. 3A and FIG. 3B, the horizontal axis represents time, and the vertical axis represents voltage. A thick solid line represents a power supply voltage, and a thin solid line (e.g., a waveform) represents a modulated signal.

In the digital ET mode, as illustrated in FIG. 3A, the power supply voltage is varied to a plurality of discrete voltage levels within one frame to track the envelope of the modulated signal. As a result, the power supply voltage signal forms a rectangular wave. In the digital ET mode, a power supply voltage level is selected or set from among a plurality of discrete voltage levels, based on an envelope signal.

For purposes of this disclosure, a frame is a unit forming an RF signal (e.g., a modulated signal). For example, in 5G NR and LTE, a frame includes 10 subframes, each subframe includes a plurality of slots, and each slot is composed of a plurality of symbols. The subframe has a length of 1 ms, and the frame has a length of 10 ms according to an exemplary aspect.

In the analog ET mode, as illustrated in FIG. 3B, the power supply voltage is continuously varied to track the envelope of the modulated signal. In the analog ET mode, the power supply voltage is determined based on an envelope signal. In the analog ET mode, when the envelope of the modulated signal changes at a high speed, it is difficult for the power supply voltage to track the envelope.

### Example 1

### [3.1. Disposition of Components of Tracker Module 100]

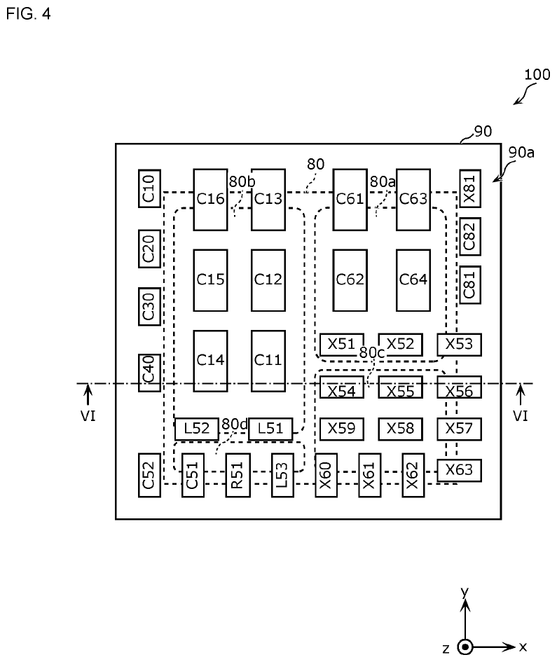

A tracker module 100 equipped with the pre-regulator circuit 10 (except for the power inductor L71), the switched-capacitor circuit 20, the supply modulator 30, the filter circuit 40, and the digital control circuit 60 will be described as a first exemplary aspect, (Example 1) of the power supply circuit 1 having the above-described configuration, with reference to FIG. 4 to FIG. 6. In the present exemplary aspect, the power inductor L71 included in the pre-regulator circuit 10 is not disposed on or in a module laminate 90 and is not included in the tracker module 100, but the exemplary aspect not limited thereto.

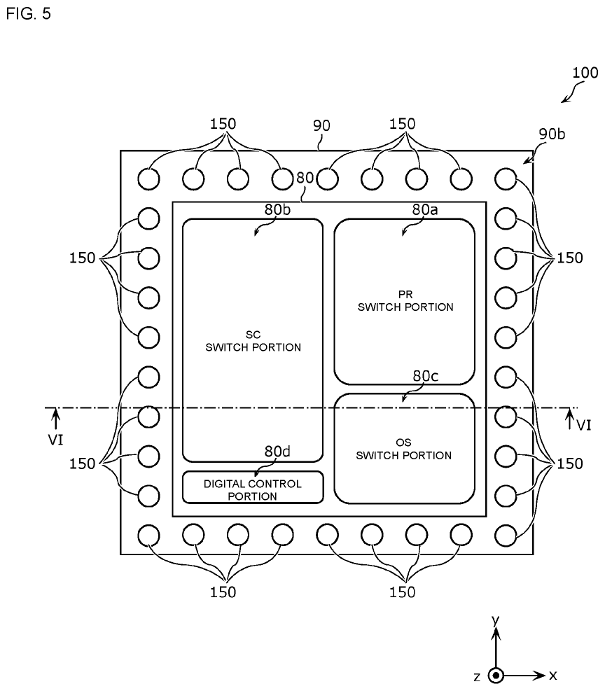

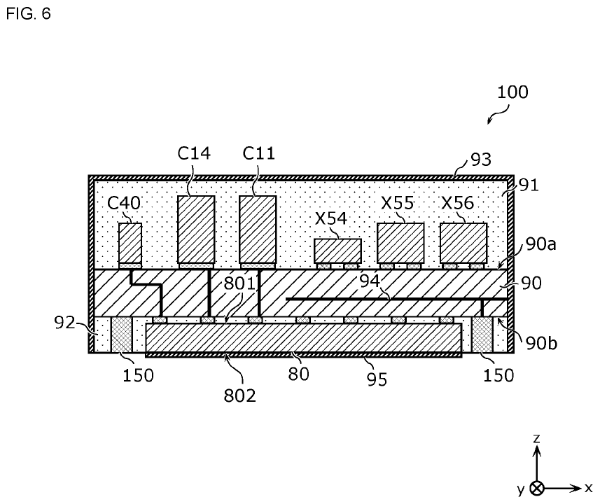

FIG. 4 is a plan view of the tracker module 100 according to the present exemplary aspect. FIG. 5 is a plan view of the tracker module 100 according to the present exemplary aspect, in which a main surface 90b side of the module laminate 90 is seen through from the positive side of the z-axis. FIG. 6 is a sectional view of the tracker module 100 according to the present exemplary aspect. The section of the tracker module 100 in FIG. 6 is a section taken along the VI-VI line in FIG. 4 and FIG. 5.

In FIG. 4 to FIG. 6, the illustration of some of wiring lines connecting a plurality of circuit components disposed on or in the module laminate 90 is omitted. In FIG. 4 and FIG. 5, the illustration of resin members 91 and 92 covering the plurality of circuit components and a shield electrode layer 93 is omitted. In FIG. 4, broken lines indicate an integrated circuit 80 disposed on the main surface 90b side and the internal configuration thereof.

The tracker module 100 includes the module laminate 90, the resin members 91 and 92, the shield electrode layer 93, a metal member 95, circuit components X51 to X63 and X81, and a plurality of post electrodes 150, in addition to the plurality of circuit components including active elements and passive elements (except for the power inductor L71) included in the pre-regulator circuit 10, the switched-capacitor circuit 20, the supply modulator 30, the filter circuit 40, and the digital control circuit 60 illustrated in FIG. 2A and FIG. 2B.

The module laminate 90 has a main surface 90a and the main surface 90b opposed to each other. The main surface 90a is an example of a first main surface, and the main surface 90b is an example of a second main surface. The module laminate 90 includes a wiring layer, via-conductors, a ground plane 94, and so forth formed therein. In FIG. 4 and FIG. 5, the module laminate 90 has a rectangular shape in a plan view, but the shape is not limited thereto and can be different shapes in alternative aspects.

It is noted that the module laminate 90 may be referred to as a “module substrate” and can be one of a low temperature co-fired ceramics (LTCC) substrate or a high temperature co-fired ceramics (HTCC) substrate having a multilayer structure of a plurality of dielectric layers, a component-embedded board, a substrate including a redistribution layer (RDL), a printed circuit board, or the like, for example. In this case, the module laminate 90 has a thickness of, for example, 175 micrometers, but the thickness is not limited thereto.

As illustrated in FIG. 4 and FIG. 6, on the main surface 90a, there are disposed the capacitors C10 to C16, C20, C30, C40, C51, C52, C61 to C64, C81, and C82; the inductors L51 to L53; the resistor R51; the circuit components X51 to X63 and X81; and the resin member 91.

In an exemplary aspect, the capacitors C10 to C16, C20, C30, C40, C51, C52, and C61 to C64 are each mounted as a chip capacitor. Accordingly, the chip capacitor can be a surface mount device (SMD) forming a capacitor. It is noted however that the implementation of the plurality of capacitors is not limited to chip capacitors. For example, the plurality of capacitors can be included in an integrated passive device (IPD) in another exemplary aspect.

In a plan view of the module laminate 90, the capacitors C11 to C16 functioning as flying capacitors of the switched-capacitor circuit 20 each have a size larger than the size of each of the capacitors C10, C20, C30, and C40 functioning as smoothing capacitors of the switched-capacitor circuit 20. That is, the regions of the capacitors C11 to C16 orthographically projected on the xy plane each have an area larger than the area of the region of each of the capacitors C10, C20, C30, and C40 orthographically projected on the xy plane.

In an exemplary aspect, the inductors L51 to L53 are each mounted as a chip inductor. Accordingly, the chip inductor is an SMD forming an inductor. However, it is noted that the implementation of the plurality of inductors is not limited to chip inductors. For example, the plurality of inductors may be included in an IPD in an alternative aspect.

In an exemplary aspect, the resistor R51 is mounted as a chip resistor. Accordingly, the chip resistor is an SMD forming a resistor. However, it is noted that the implementation of the resistor R51 is not limited to a chip resistor. For example, the resistor R51 may be included in an IPD in an alternative aspect.

According to this configuration, the plurality of capacitors, the plurality of inductors, and the resistor disposed on the main surface 90a are grouped and disposed for each circuit.

Specifically, a group of the capacitors C61 to C64 included in the pre-regulator circuit 10 is disposed so as to overlap a PR switch portion 80a in the integrated circuit 80 in a plan view of the module laminate 90. Accordingly, a group of the circuit components included in the pre-regulator circuit 10 is disposed close to the PR switch portion 80a in the integrated circuit 80. As a result, the PR switch portion 80a is disposed closer to each of the capacitors C61 to C64 than an SC switch portion 80b and an OS switch portion 80c.

A group of the capacitors C10 to C16, C20, C30, and C40 included in the switched-capacitor circuit 20 is disposed so as to overlap the SC switch portion 80b in the integrated circuit 80 in a plan view of the module laminate 90. Accordingly, a group of the circuit components included in the switched-capacitor circuit 20 is disposed close to the SC switch portion 80b in the integrated circuit 80. As a result, the SC switch portion 80b is disposed closer to each of the capacitors C10 to C16, C20, C30, and C40 than the PR switch portion 80a and the OS switch portion 80c.

Each of the capacitors C11 to C16 overlaps the integrated circuit 80 in a plan view of the module laminate 90. More specifically, in a plan view of the module laminate 90, the capacitors C11 to C16 overlap the SC switch portion 80b in the integrated circuit 80 but do not overlap the PR switch portion 80a, the OS switch portion 80c, or a digital control portion 80d in the integrated circuit 80. On the other hand, the capacitors C10, C20, C30, and C40 included in the switched-capacitor circuit 20 do not overlap the integrated circuit 80.

In the present exemplary aspect, each of the capacitors C11 to C16 overlaps the integrated circuit 80, but the exemplary aspect is not limited thereto. For example, a capacitor to which a higher potential is applied among the capacitors C11 to C16 may be preferentially disposed so as to overlap the integrated circuit 80. Specifically, each of the capacitors C11 and C14 to which a potential higher than a potential applied to the capacitors C13 and C16 is applied may overlap the integrated circuit 80, and each of the capacitors C13 and C16 may not overlap the integrated circuit 80 in an alternative aspect. In this case, only one of the capacitors C11 and C14 may overlap the integrated circuit 80.

In the present exemplary aspect, the capacitors C11 to C16 do not overlap the PR switch portion 80a, the OS switch portion 80c, or the digital control portion 80d in the integrated circuit 80 in a plan view of the module laminate 90, but the exemplary aspect is not limited thereto. That is, at least one of the capacitors C11 to C16 may overlap the PR switch portion 80a, the OS switch portion 80c, or the digital control portion 80d in a plan view of the module laminate 90 according to an alternative exemplary aspect.

In the present exemplary aspect, the capacitors C10, C20, C30, and C40 do not overlap the integrated circuit 80 in a plan view of the module laminate 90, but the exemplary aspect is not limited to this configuration. That is, at least one of the capacitors C10, C20, C30, and C40 may overlap the integrated circuit 80 in a plan view of the module laminate 90 in an alternative aspect.

A group of the capacitors C51 and C52, the inductors L51 to L53, and the resistor R51 included in the filter circuit 40 is disposed in a region on the main surface 90a sandwiched between a straight line along the lower side of the integrated circuit 80 and a straight line along the lower side of the module laminate 90 in a plan view of the module laminate 90. Accordingly, a group of the circuit components included in the filter circuit 40 is disposed close to the OS switch portion 80c in the integrated circuit 80. As a result, the OS switch portion 80c is disposed closer to each of the capacitors C51 and C52, the inductors L51 to L53, and the resistor R51 than the PR switch portion 80a and the SC switch portion 80b.

The circuit components X51 to X63 and X81 are optional circuit components that are not essential to the present disclosure.

The shortest distance between any two circuit components on the main surface 90a is, for example, 100 micrometers, but this configuration is not so limited.

The resin member 91 covers the main surface 90a and at least a part of the plurality of electronic components on the main surface 90a. The resin member 91 has a function of ensuring reliability, such as mechanical strength and moisture resistance, of the plurality of electronic components on the main surface 90a. It is noted that the resin member 91 may not be included in the tracker module 100 in an alternative aspect.

As illustrated in FIG. 5 and FIG. 6, on the main surface 90b, there are disposed the integrated circuit 80, the resin member 92, the metal member 95, and the plurality of post electrodes 150.

The integrated circuit 80 is disposed in a central region on the main surface 90b. The ground plane 94 is disposed between the integrated circuit 80 and the capacitors C11 to C16 included in the switched-capacitor circuit 20.

The integrated circuit 80 includes the PR switch portion 80a, the SC switch portion 80b, the OS switch portion 80c, and the digital control portion 80d. The PR switch portion 80a is an example of a third switch portion and includes the switches S61 to S63, S71, and S72. The SC switch portion 80b is an example of a first switch portion and includes the switches S11 to S14, S21 to S24, S31 to S34, and S41 to S44. The OS switch portion 80c is an example of a second switch portion and includes the switches S51 to S54. The digital control portion 80d includes the first controller 61 and the second controller 62 in an exemplary aspect.

As illustrated in FIG. 6, the integrated circuit 80 has a main surface 801 facing the module laminate 90 and a main surface 802 opposed to the main surface 801. The main surface 801 is an example of a third main surface, and the main surface 802 is an example of a fourth main surface. A plurality of terminals is disposed on the main surface 801, and the metal member 95 is disposed on the main surface 802. The shortest distance between the plurality of terminals disposed on the main surface 801 and the outer edge of the integrated circuit 80 is, for example, 150 micrometers, but is not limited thereto.

In FIG. 5, the PR switch portion 80a, the SC switch portion 80b, the OS switch portion 80c, and the digital control portion 80d are included in the single integrated circuit 80, but the configuration is not limited thereto. For example, the PR switch portion 80a and the SC switch portion 80b may be included in an integrated circuit, and the OS switch portion 80c may be included in another integrated circuit. Alternatively, for example, the SC switch portion 80b and the OS switch portion 80c may be included in an integrated circuit, and the PR switch portion 80a may be included in another integrated circuit. Alternatively, the PR switch portion 80a and the OS switch portion 80c may be included in an integrated circuit, and the SC switch portion 80b may be included in another integrated circuit. Alternatively, for example, the PR switch portion 80a, the SC switch portion 80b, and the OS switch portion 80c may be included in three respective integrated circuits. In this case, the digital control portion 80d may be included in each of the plurality of integrated circuits or may be included in only one of the pluralities of integrated circuits.

In FIG. 5, the integrated circuit 80 has a rectangular shape in a plan view of the module laminate 90, but the shape is not limited thereto and can be different shapes in alternative aspects.

According to an exemplary aspect, the integrated circuit 80 can be formed by using, for example, complementary metal oxide semiconductor (CMOS), and specifically may be manufactured by a silicon on insulator (SOI) process. However, it is noted that the integrated circuit 80 is not limited to CMOS.

The metal member 95 is in contact with the main surface 802 of the integrated circuit 80. In the present exemplary aspect, the metal member 95 is a metal layer covering the entirety or a part of the main surface 802 The metal member 95 is physically connected to a ground terminal or the like on a mother board (not illustrated) disposed in the z-axis negative direction of the tracker module 100.

The shape of the metal member 95 is not particularly limited. For example, the metal member 95 may be a member having a plurality of recessed portions or may be one or more metal chips. The material of the metal member 95 may be copper, gold, aluminum, or an alloy containing these metals, but is not limited thereto. The metal member 95 may not be included in the tracker module 100 in an alternative aspect.

The plurality of post electrodes 150 function as a plurality of external connection terminals including a ground terminal in addition to the input terminal 110, the output terminal 141, the inductor connection terminals 115 and 116, and the control terminals 601 to 604 illustrated in FIG. 2A.

The plurality of post electrodes 150 are electrically connected to an input/output terminal and/or a ground terminal or the like on the mother board (not illustrated) disposed in the z-axis negative direction of the tracker module 100. The plurality of post electrodes 150 are electrically connected to the plurality of electronic components disposed on the main surface 90a via the via-conductors or the like formed in the module laminate 90.

The plurality of post electrodes 150 may be, but are not limited to, copper electrodes. For example, the plurality of post electrodes 150 may be solder electrodes. Instead of the plurality of post electrodes 150, a plurality of bump electrodes may be used as the plurality of external connection terminals.

The resin member 92 covers the main surface 90b and at least a part of the plurality of electronic components on the main surface 90b. The resin member 92 has a function of ensuring reliability, such as mechanical strength and moisture resistance, of the plurality of electronic components on the main surface 90b. It is noted that the resin member 92 may not be included in the tracker module 100 in an alternative aspect.

The shield electrode layer 93 is a metal thin film formed by sputtering, for example. The shield electrode layer 93 is formed so as to cover the surfaces (e.g., the upper surface and side surfaces) of the resin member 91. The shield electrode layer 93 is connected to ground and reduces entry of external noise into the electronic components forming the tracker module 100 and interference of noise generated in the tracker module 100 with another module or another device. It is noted that the shield electrode layer 93 may not be included in the tracker module 100 in an alternative aspect.

It should be appreciated that the configuration of the tracker module 100 according to the present exemplary aspect is illustrative and is not restrictive. For example, one or some of the capacitors and inductors disposed on the main surface 90a may be formed in the module laminate 90. In addition, one or some of the capacitors and inductors disposed on the main surface 90a are not necessarily on or in the module laminate 90 and are not included in the tracker module 100.

### [3.2. Advantageous Effects]

As described above, the tracker module 100 according to the present exemplary aspect includes the module laminate 90 having the main surfaces 90a and 90b opposed to each other, the integrated circuit 80 disposed on one of the main surfaces 90a and 90b of the module laminate 90, and at least one capacitor (for example, the capacitor C11) included in the switched-capacitor circuit 20 and disposed on the other of the main surfaces 90a and 90b of the module laminate 90. The switched-capacitor circuit 20 is configured to generate, based on an input voltage, a plurality of discrete voltages. The integrated circuit 80 includes at least one switch included in the switched-capacitor circuit 20, and at least one switch included in the supply modulator 30 configured to selectively output, based on an envelope signal, at least one of the plurality of discrete voltages. The at least one capacitor (for example, the capacitor C11) overlaps the integrated circuit 80 in a plan view of the module laminate 90.

In other words, the tracker module 100 according to the present exemplary aspect includes the module laminate 90 having the main surfaces 90a and 90b opposed to each other, the integrated circuit 80 disposed on one of the main surfaces 90a and 90b of the module laminate 90, and at least one capacitor (for example, the capacitor C11) included in the switched-capacitor circuit 20 and disposed on the other of the main surfaces 90a and 90b of the module laminate 90. The switched-capacitor circuit 20 is configured to generate, based on an input voltage, a plurality of discrete voltages. The integrated circuit 80 includes at least one switch included in the switched-capacitor circuit 20, and at least one switch included in the supply modulator 30 that is connected to the digital control circuit 60 and that is configured to selectively output at least one of the plurality of discrete voltages. The at least one capacitor (for example, the capacitor C11) overlaps the integrated circuit 80 in a plan view of the module laminate 90.

From another viewpoint, the tracker module 100 according to the present exemplary aspect includes the module laminate 90 having the main surfaces 90a and 90b opposed to each other, the integrated circuit 80 disposed on one of the main surfaces 90a and 90b of the module laminate 90, and at least one capacitor included in the switched-capacitor circuit 20 and disposed on the other of the main surfaces 90a and 90b of the module laminate 90. The integrated circuit 80 includes at least one switch included in the switched-capacitor circuit 20, and at least one switch included in the supply modulator 30. The at least one capacitor included in the switched-capacitor circuit 20 includes the capacitor C11 having a first electrode and a second electrode, and the capacitor C14 having a third electrode and a fourth electrode. The at least one switch included in the switched-capacitor circuit 20 includes the switches S11 to S14 and the switches S21 to S24. A first end of the switch S11 and a first end of the switch S12 are connected to the first electrode of the capacitor C11. A first end of the switch S22 and a first end of the switch S21 are connected to the second electrode of the capacitor C11. A first end of the switch S13 and a first end of the switch S14 are connected to the third electrode of the capacitor C14. A first end of the switch S24 and a first end of the switch S23 are connected to the fourth electrode of the capacitor C14. The second ends of the switch S11, the switch S22, the switch S13, and the switch S24 are connected to each other. Moreover, the second end of the switch S12 is connected to the second end of the switch S14. The second end of the switch S21 is connected to the second end of the switch S23. The supply modulator 30 includes the output terminal 130. The at least one switch included in the supply modulator 30 includes the switch S52 connected between the output terminal 130 and each of the second ends of the switch S11, the switch S22, the switch S13, and the switch S24; and the switch S51 connected between the output terminal 130 and each of the second ends of the switch S12 and the switch S14. The at least one capacitor (for example, the capacitors C11 and C14) overlaps the integrated circuit 80 in a plan view of the module laminate 90.

Accordingly, the at least one capacitor (for example, the capacitor C11) included in the switched-capacitor circuit 20 is disposed on the main surface different from the main surface having disposed thereon the integrated circuit 80 including the switch (for example, the switch S11) included in the switched-capacitor circuit 20. That is, circuit components are disposed on both the main surfaces of the module laminate 90, and thus the tracker module 100 can be reduced in size. Furthermore, in the tracker module 100, the at least one capacitor (for example, the capacitor C11) overlaps the integrated circuit 80 in a plan view of the module laminate 90. At this time, the distance between the capacitor and the integrated circuit 80 corresponds to the thickness of the module laminate 90. Typically, the thickness of the module laminate 90 can be smaller than the shortest distance between terminals of two circuit components on the same main surface. Thus, the wiring length is shorter when two circuit components disposed on different main surfaces are connected to each other by a via-conductor than when two circuit components disposed on the same main surface are connected to each other by a planar wiring pattern. That is, the wiring length can be shortened between the capacitor (for example, the capacitor C11) and the switch (for example, the switch S11) included in the switched-capacitor circuit 20, reduce the resistance loss and parasitic capacitance in the wiring line of the switched-capacitor circuit 20, and reduce deterioration of output characteristics.

For example, in the tracker module 100 according to the present exemplary aspect, the integrated circuit 80 may include the SC switch portion 80b including the at least one switch included in the switched-capacitor circuit 20, and the OS switch portion 80c including the at least one switch included in the supply modulator 30. The at least one capacitor (for example, the capacitor C11) may overlap the SC switch portion 80b in a plan view of the module laminate 90.

Accordingly, the at least one capacitor included in the switched-capacitor circuit 20 overlaps the SC switch portion 80b in a plan view of the module laminate 90. Thus, the wiring length can be shortened between the capacitor (for example, the capacitor C11) and the switch (for example, the switch S11) included in the switched-capacitor circuit 20, and effectively reduce the resistance loss and parasitic capacitance in the wiring line of the switched-capacitor circuit 20.

For example, in the tracker module 100 according to the present exemplary aspect, the integrated circuit 80 may further include the PR switch portion 80a including at least one switch included in the pre-regulator circuit 10 configured to convert the input voltage into a first voltage and output the first voltage to the switched-capacitor circuit 20. It should be appreciated that the at least one capacitor (for example, the capacitor C11) does not overlap the PR switch portion 80a in a plan view of the module laminate 90 according to an alternative aspect.

Accordingly, the at least one capacitor included in the switched-capacitor circuit 20 does not overlap the PR switch portion 80a in a plan view of the module laminate 90. Thus, heat transfer from the PR switch portion 80a to the capacitor of the switched-capacitor circuit 20 can be reduced, and an influence of the heat generated in the PR switch portion 80a on the switched-capacitor circuit 20 can be reduced. In particular, the amount of heat generated in the PR switch portion 80a is large, and thus the effect thereof is also large.

For example, in the tracker module 100 according to the present exemplary aspect, the at least one capacitor may include at least one flying capacitor (for example, the capacitor C11). The at least one flying capacitor may overlap the integrated circuit 80 in a plan view of the module laminate 90.

Accordingly, the wiring length can be shortened between the flying capacitor (for example, the capacitor C11) and the switch (for example, the switch S11) included in the switched-capacitor circuit 20, and effectively reduce the resistance loss and parasitic capacitance in the wiring line of the switched-capacitor circuit 20. In particular, a current that flows through the wiring line connecting the flying capacitor and the switch is larger than a current that flows through the wiring line connecting the smoothing capacitor and the switch, and thus the effect of reducing the resistance loss is large.

For example, in the tracker module 100 according to the present exemplary aspect, the at least one capacitor may further include at least one smoothing capacitor (for example, the capacitor C10). According to an exemplary aspect, I at least one smoothing capacitor does not overlap the integrated circuit 80 in a plan view of the module laminate 90.

Accordingly, the flying capacitor is preferentially overlapped with the integrated circuit 80 over the smoothing capacitor. Thus, the length of the wiring line is preferably shortened that connects the flying capacitor and the switch and through which a current larger than a current that flows through the wiring line which connects the smoothing capacitor and the switch flows, and the resistance loss in the wiring line of the switched-capacitor circuit 20 can more effectively be reduced.

For example, in the tracker module 100 according to the present exemplary aspect, the at least one flying capacitor may include a first flying capacitor (for example, the capacitor C11), a second flying capacitor (for example, the capacitor C14), a third flying capacitor (for example, the capacitor C13), and a fourth flying capacitor (for example, the capacitor C16). The first flying capacitor may be subjected to a potential higher than a potential applied to the third flying capacitor. The second flying capacitor may be subjected to a potential higher than a potential applied to the fourth flying capacitor. At least one of the first flying capacitor and the second flying capacitor may overlap the integrated circuit 80 in a plan view of the module laminate 90.

Accordingly, at least one of the first flying capacitor and the second flying capacitor to which a higher potential is applied is preferentially overlapped with the integrated circuit 80. Thus, the length of the wiring line can preferably be shortened through which a larger current flows, and the resistance loss in the wiring line of the switched-capacitor circuit 20 can more effectively be reduced.

For example, in the tracker module 100 according to the present exemplary aspect, each of the first flying capacitor (for example, the capacitor C11) and the second flying capacitor (for example, the capacitor C14) may overlap the integrated circuit 80 in a plan view of the module laminate 90.

Accordingly, both the first flying capacitor and the second flying capacitor to which a higher potential is applied are preferentially overlapped with the integrated circuit 80. Thus, the length of the wiring line can preferably be shortened through which a larger current flows, and the resistance loss in the wiring line of the switched-capacitor circuit 20 can more effectively be reduced.

For example, in the tracker module 100 according to the present exemplary aspect, at least one of the third flying capacitor (for example, the capacitor C13) and the fourth flying capacitor (for example, the capacitor C16) does not overlap the integrated circuit 80 in a plan view of the module laminate 90.

Accordingly, the first flying capacitor and the second flying capacitor to which a higher potential is applied are preferentially overlapped with the integrated circuit 80 over the third flying capacitor and the fourth flying capacitor to which a lower potential is applied. Thus, the length of the wiring line can preferably be shortened that connects the first flying capacitor or the second flying capacitor and the switch and through which a current larger than a current that flows through the wiring line which connects the third flying capacitor or the fourth flying capacitor and the switch flows, and the resistance loss in the wiring line of the switched-capacitor circuit 20 can more effectively be reduced.

For example, in the tracker module 100 according to the present exemplary aspect, the module laminate 90 may include the ground plane 94 connected to ground. The ground plane 94 may be disposed between the at least one capacitor (for example, the capacitor C11) and the integrated circuit 80.

According to this configuration, capacitive coupling and/or inductive coupling between the at least one capacitor included in the switched-capacitor circuit 20 and the integrated circuit 80 can be reduced.

For example, the tracker module 100 according to the present exemplary aspect may further include the plurality of post electrodes 150 disposed on the main surface 90b. The at least one capacitor (for example, the capacitor C11) may be disposed on the main surface 90a, and the integrated circuit 80 may be disposed on the main surface 90b.

Accordingly, the integrated circuit 80 having a relatively low height is disposed on the main surface 90b on which the plurality of post electrodes 150 are disposed. Thus, the height of each of the plurality of post electrodes 150 can be reduced, and the height of the tracker module 100 can be reduced.

For example, in the tracker module 100 according to the present exemplary aspect, the integrated circuit 80 may have the main surface 801 facing the module laminate 90 and the main surface 802 opposed to the main surface 801. The tracker module 100 may further include the metal member 95 that is in contact with the main surface 802.

Accordingly, the metal member 95 is in contact with the integrated circuit 80, and thus the heat of the integrated circuit 80 can be effectively dissipated via the metal member 95.

In the tracker module 100 according to the present exemplary aspect, the metal member 95 may be connected to ground and include a metal layer covering at least a part of the main surface 802.

Accordingly, at least a part of the main surface 802 of the integrated circuit 80 is covered with the metal member 95 connected to ground, and thus external noise can be reduced from entering the integrated circuit 80 and interference of noise generated in the integrated circuit 80 with another module or another device can also be reduced.

### Example 2

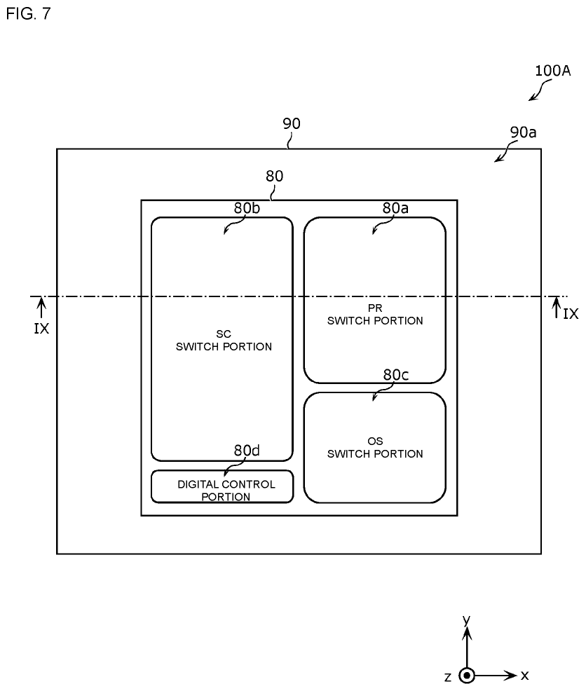

Next, a tracker module 100A will be described as a second exemplary aspect (Example 2) of the power supply circuit 1. The present exemplary aspect is different from the above-described Example 1 in that the integrated circuit 80 is disposed on the main surface 90a of the module laminate 90. Hereinafter, the tracker module 100A according to the present exemplary aspect will be described with a focus on differences from the above-described Example 1 with reference to FIG. 7 to FIG. 9.

### [4.1. Disposition of Components of Tracker Module 100A]

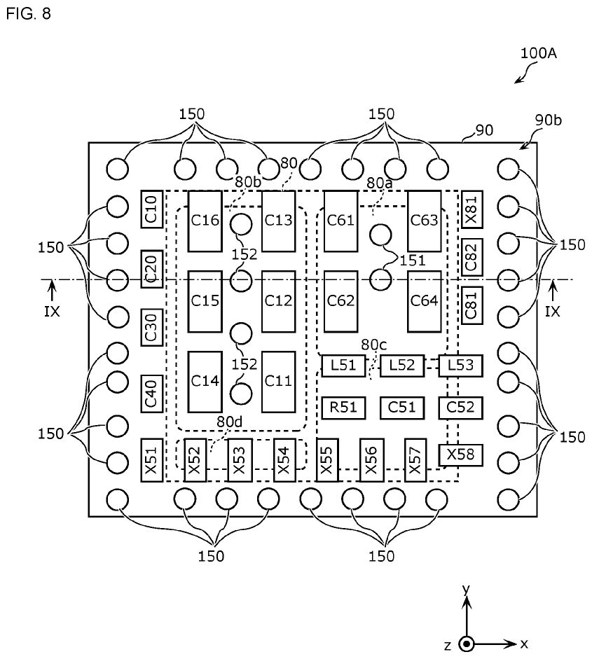

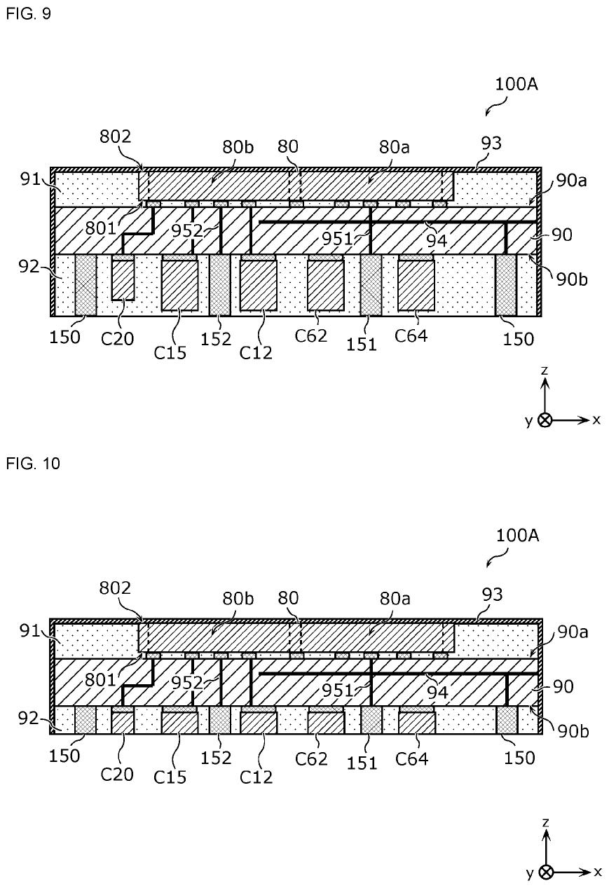

FIG. 7 is a plan view of the tracker module 100A according to the present exemplary aspect. FIG. 8 is a plan view of the tracker module 100A according to the present exemplary aspect, in which the main surface 90b side of the module laminate 90 is seen through from the positive side of the z-axis. FIG. 9 is a sectional view of the tracker module 100A according to the present exemplary aspect. The section of the tracker module 100A in FIG. 9 is a section taken along the IX-IX line in FIG. 7 and FIG. 8.

In FIG. 7 to FIG. 9, some of wiring lines connecting a plurality of circuit components disposed on or in the module laminate 90 are not illustrated. In FIG. 7 and FIG. 8, the illustration of the resin members 91 and 92 and the shield electrode layer 93 is omitted. In FIG. 8, broken lines indicate the integrated circuit 80 disposed on the main surface 90a side and the internal configuration thereof.

The tracker module 100A according to the present exemplary aspect includes the module laminate 90, the resin members 91 and 92, the shield electrode layer 93, the circuit components X51 to X58 and X81, and the plurality of post electrodes 150, in addition to the plurality of circuit components (except for the power inductor L71) including active elements and passive elements included in the pre-regulator circuit 10, the switched-capacitor circuit 20, the supply modulator 30, the filter circuit 40, and the digital control circuit 60 illustrated in FIG. 2A and FIG. 2B.

As illustrated in FIG. 7 and FIG. 9, on the main surface 90a, there are disposed the integrated circuit 80 and the resin member 91. As illustrated in FIG. 8 and FIG. 9, on the main surface 90b, there are disposed the capacitors C10 to C16, C20, C30, C40, C51, C52, C61 to C64, C81, and C82; the inductors L51 to L53; the resistor R51; the circuit components X51 to X58 and X81; the resin member 92, and the plurality of post electrodes 150. It is noted that the circuit components X51 to X58 and X81 are optional circuit components according to an exemplary aspect.

As illustrated in FIG. 9, the integrated circuit 80 has the main surface 801 facing the module laminate 90 and the main surface 802 opposed to the main surface 801. The main surface 801 is an example of a third main surface, and the main surface 802 is an example of a fourth main surface. The main surface 802 is in contact with the shield electrode layer 93. That is, at least a part of the main surface 802 is in contact with at least a part of the shield electrode layer 93.

The PR switch portion 80a in the integrated circuit 80 is connected to a post electrode 151 (an example of a first external connection terminal) included in the plurality of post electrodes 150 via a via-conductor 951 (an example of a first via-conductor) in the module laminate 90. The PR switch portion 80a overlaps the via-conductor 951 and the post electrode 151 in a plan view of the module laminate 90.

The SC switch portion 80b in the integrated circuit 80 is connected to a post electrode 152 (an example of a second external connection terminal) included in the plurality of post electrodes 150 via a via-conductor 952 (an example of a second via-conductor) in the module laminate 90. The SC switch portion 80b overlaps the via-conductor 952 and the post electrode 152 in a plan view of the module laminate 90.

The via-conductors 951 and 952 are each a through via in the module laminate 90. The via-conductors 951 and 952 are each not limited to a through via. For example, the via-conductors 951 and 952 each may be a combination of a blind via exposed on the main surface 90a side and a blind via exposed on the main surface 90b side in alternative aspects.

The capacitors C11 to C16 each overlap the integrated circuit 80 in a plan view of the module laminate 90. More specifically, in a plan view of the module laminate 90, the capacitors C11 to C16 overlap the SC switch portion 80b in the integrated circuit 80 but do not overlap the PR switch portion 80a, the OS switch portion 80c, or the digital control portion 80d in the integrated circuit 80. On the other hand, the capacitors C10, C20, C30, and C40 included in the switched-capacitor circuit 20 do not overlap the integrated circuit 80.

The shield electrode layer 93 is an example of a metal layer and covers the main surface 90a of the module laminate 90 and at least a part of the circuit components on the main surface 90a. As described above, the shield electrode layer 93 is in contact with the main surface 802 of the integrated circuit 80. Specifically, the shield electrode layer 93 covers the entirety of the main surface 802 of the integrated circuit 80. It is noted that the shield electrode layer 93 is not necessarily in contact with the main surface 802 of the integrated circuit 80, and is not necessarily included in the tracker module 100A.

It should be appreciated that the configuration of the tracker module 100A according to the present exemplary aspect is illustrative and is not restrictive. For example, one or some of the capacitors and inductors disposed on the main surface 90b may be formed in the module laminate 90. In addition, one or some of the capacitors and inductors disposed on the main surface 90b are not on or in the module laminate 90 and are not included in the tracker module 100A.

### [4.2. Advantageous Effects]

As described above, the tracker module 100A according to the present exemplary aspect may further include the plurality of post electrodes 150 disposed on the main surface 90b. The integrated circuit 80 may be disposed on the main surface 90a, and the at least one capacitor (for example, the capacitor C11) may be disposed on the main surface 90b.

Accordingly, the integrated circuit 80 can be disposed on the main surface 90a opposite to the main surface 90b on which the plurality of post electrodes 150 are disposed.

As described above, in the tracker module 100A according to the present exemplary aspect, the integrated circuit 80 may include the SC switch portion 80b including the at least one switch included in the switched-capacitor circuit 20, the OS switch portion 80c including the at least one switch included in the supply modulator 30, and the PR switch portion 80a including at least one switch included in the pre-regulator circuit 10 configured to convert the input voltage into a first voltage and output the first voltage to the switched-capacitor circuit 20. The PR switch portion 80a may be connected to the post electrode 151 included in the plurality of post electrodes 150 via the via-conductor 951 in the module laminate 90. The PR switch portion 80a may overlap the via-conductor 951 and the post electrode 151 in a plan view of the module laminate 90.

Accordingly, the PR switch portion 80a is connected to the post electrode 151 via the via-conductor 951. Thus, the heat from the PR switch portion 80c, which generates a larger amount of heat than the OS switch portion 80a and the like, can be effectively dissipated via the via-conductor 951 and the post electrode 151.

As described above, in the tracker module 100A according to the present exemplary aspect, the SC switch portion 80b may be connected to the post electrode 152 included in the plurality of post electrodes 150 via the via-conductor 952 in the module laminate 90. The SC switch portion 80b may overlap the via-conductor 952 and the post electrode 152 in a plan view of the module laminate 90.

Accordingly, the SC switch portion 80b is connected to the post electrode 152 via the via-conductor 952. Thus, the heat from the SC switch portion 80b, which generates a larger amount of heat than the OS switch portion 80c and the like, can be effectively dissipated via the via-conductor 952 and the post electrode 152.

As described above, in the tracker module 100A according to the present exemplary aspect, the integrated circuit 80 may have the main surface 801 facing the module laminate 90 and the main surface 802 opposed to the main surface 801. The tracker module 100A may further include the resin member 91 covering the main surface 90a of the module laminate 90 and at least a part of a circuit component on the main surface 90a, and the shield electrode layer 93 covering at least a part of the surface of the resin member 91. The shield electrode layer 93 may be in contact with the main surface 802.

Accordingly, the heat of the integrated circuit 80 can be dissipated via the shield electrode layer 93, and the heat dissipation property of the integrated circuit 80 can be improved.

In the present exemplary aspect, at least a part of the capacitors C10 to C16, C20, C30, C40, C51, C52, C61 to C64, C81, and C82; the inductors L51 to L53; the resistor R51; and the circuit components X51 to X58 and X81 that are disposed on the main surface 90b may be made of a material that can be ground (for example, silicon). In this case, the circuit components disposed on the main surface 90b can be cut away, and the height of the tracker module 100A can be further reduced as illustrated in FIG. 10.

### Additional Exemplary Embodiments

The tracker module according to the exemplary aspects has been described above based on an embodiment and examples. However, it is noted that the tracker module disclosed herein is not limited to the above embodiment and examples. Additional embodiments can be implemented by combining any constituent elements in the above embodiment and examples, modifications obtained by applying various changes conceived by those skilled in the art to the above embodiment and examples without departing from the gist of the exemplary aspects. Moreover, various devices including the above-described tracker module can also be provided as would be appreciated to one skilled in the art.

For example, in the circuit configurations of the various circuits according to the above embodiment, another circuit element, wiring line, and the like may be inserted between individual circuit elements and paths connecting signal paths disclosed in the drawings. For example, an impedance matching circuit may be inserted between the PA 2 and the filter 3 and/or between the filter 3 and the antenna 6.

### INDUSTRIAL APPLICABILITY

The exemplary aspects of the present disclosure can be widely used, as a tracker module for supplying a power supply voltage to a power amplifier in communication devices such as mobile phones.

### REFERENCE SIGNS LIST

1 power supply circuit
2 power amplifier
3 filter
4 PA control circuit
5 RFIC
6 antenna
7 communication device
10 pre-regulator circuit
20 switched-capacitor circuit
30 supply modulator
40 filter circuit
50 DC power source
60 digital control circuit
61 first controller
62 second controller
80 integrated circuit
80a PR switch portion
80b SC switch portion
80c OS switch portion
80d digital control portion
90 module laminate
90a, 90b, 801, 802 main surface
91, 92 resin member
93 shield electrode layer
94 ground plane
95 metal member
100, 100A tracker module
110, 131, 132, 133, 134, 140 input terminal
111, 112, 113, 114, 130, 141 output terminal
115, 116 inductor connection terminal
150, 151, 152 post electrode
601, 602, 603, 604 control terminal
951, 952 via-conductor
C10, C11, C12, C13, C14, C15, C16, C20, C30, C40, C51, C52, C61, C62, C63, C64, C81, C82 capacitor
L51, L52, L53 inductor
L71 power inductor
N1, N2, N3, N4 node
R51 resistor
S11, S12, S13, S14, S21, S22, S23, S24, S31, S32, S33, S34, S41, S42, S43, S44, S51, S52, S53, S54, S61, S62, S63, S71, S72 switch
V1, V2, V3, V4 voltage

1. A tracker module comprising:
a module laminate having a first main surface and a second main surface that oppose to each other;
at least one integrated circuit on the first main surface of the module laminate; and
at least one capacitor included in a switched-capacitor circuit and that is on the second main surface of the module laminate, the switched-capacitor circuit being configured to generate a plurality of discrete voltages based on an input voltage,
wherein the at least one integrated circuit includes:
at least one switch included in the switched-capacitor circuit; and
at least one switch included in a supply modulator that is configured to selectively output, based on an envelope signal, at least one of the plurality of discrete voltages, and
wherein the at least one capacitor overlaps the at least one integrated circuit in a plan view of the module laminate.

2. The tracker module according to claim 1, wherein the at least one integrated circuit includes:
a first switch portion including the at least one switch included in the switched-capacitor circuit; and
a second switch portion including the at least one switch included in the supply modulator,
wherein the at least one capacitor overlaps the first switch portion in the plan view of the module laminate.

3. The tracker module according to claim 2, wherein:
the at least one integrated circuit further includes a third switch portion including at least one switch included in a pre-regulator circuit that is configured to convert the input voltage into a first voltage and output the first voltage to the switched-capacitor circuit, and
the at least one capacitor does not overlap the third switch portion in the plan view of the module laminate.

4. The tracker module according to claim 1, wherein the at least one capacitor includes at least one flying capacitor that overlaps the at least one integrated circuit in the plan view of the module laminate.

5. The tracker module according to claim 4, wherein the at least one capacitor further includes at least one smoothing capacitor that does not overlap the at least one integrated circuit in the plan view of the module laminate.

6. The tracker module according to claim 4, wherein:
the at least one flying capacitor includes a first flying capacitor, a second flying capacitor, a third flying capacitor, and a fourth flying capacitor,
a potential is applied to the first flying capacitor that is higher than a potential applied to the third flying capacitor,
a potential is applied to the second flying capacitor that is higher than a potential applied to the fourth flying capacitor, and
at least one of the first flying capacitor and the second flying capacitor overlaps the at least one integrated circuit in the plan view of the module laminate.

7. The tracker module according to claim 6, wherein each of the first flying capacitor and the second flying capacitor overlaps the at least one integrated circuit in the plan view of the module laminate.

8. The tracker module according to claim 6, wherein at least one of the third flying capacitor and the fourth flying capacitor does not overlap the at least one integrated circuit in the plan view of the module laminate.

9. The tracker module according to claim 1, wherein the module laminate includes a ground plane that is disposed between the at least one capacitor and the at least one integrated circuit.

10. The tracker module according to claim 1, further comprising a plurality of external connection terminals on the first main surface.

11. The tracker module according to claim 10, wherein:
the at least one integrated circuit has a third main surface facing the module laminate and a fourth main surface opposed to the third main surface, and
a metal member is in contact with the fourth main surface.

12. The tracker module according to claim 11, wherein the metal member is connected to ground and includes a metal layer that covers at least a part of the fourth main surface.

13. The tracker module according to claim 1, further comprising a plurality of external connection terminals disposed on the second main surface.

14. The tracker module according to claim 13, wherein the at least one integrated circuit includes:
a first switch portion including the at least one switch included in the switched-capacitor circuit;
a second switch portion including the at least one switch included in the supply modulator; and
a third switch portion including at least one switch included in a pre-regulator circuit that is configured to convert the input voltage into a first voltage and output the first voltage to the switched-capacitor circuit,
wherein the third switch portion is connected to a first external connection terminal included in the plurality of external connection terminals via a first via-conductor in the module laminate, and the third switch portion overlaps the first via-conductor and the first external connection terminal in the plan view of the module laminate.

15. The tracker module according to claim 14, wherein:
the first switch portion is connected to a second external connection terminal included in the plurality of external connection terminals via a second via-conductor in the module laminate, and
the first switch portion overlaps the second via-conductor and the second external connection terminal in the plan view of the module laminate.

16. The tracker module according to claim 13, wherein:
the at least one integrated circuit has a third main surface facing the module laminate and a fourth main surface opposed to the third main surface,
a resin member covers the first main surface of the module laminate and at least a part of a circuit component on the first main surface; and
a metal layer covers at least a part of a surface of the resin member and contacts the fourth main surface.

17. A tracker module comprising:
a module laminate having a first main surface and a second main surface that oppose each other;
at least one integrated circuit on the first main surface of the module laminate; and
at least one capacitor included in a switched-capacitor circuit and that is on the second main surface of the module laminate, the switched-capacitor circuit being configured to generate a plurality of discrete voltages based on an input voltage,
wherein the at least one integrated circuit includes:
at least one switch included in the switched-capacitor circuit; and
at least one switch included in a supply modulator that is connected to a digital control circuit and that is configured to selectively output at least one of the plurality of discrete voltages, and
wherein the at least one capacitor overlaps the at least one integrated circuit in a plan view of the module laminate.

18. The tracker module according to claim 17, wherein the at least one integrated circuit includes:
a first switch portion including the at least one switch included in the switched-capacitor circuit; and
a second switch portion including the at least one switch included in the supply modulator,
wherein the at least one capacitor overlaps the first switch portion in the plan view of the module laminate.

19. The tracker module according to claim 18, wherein:
the at least one integrated circuit further includes a third switch portion including at least one switch included in a pre-regulator circuit that is configured to convert the input voltage into a first voltage and output the first voltage to the switched-capacitor circuit, and
the at least one capacitor does not overlap the third switch portion in the plan view of the module laminate.

20. A tracker module comprising:
a module laminate having a first main surface and a second main surface that oppose to each other;
at least one integrated circuit on the first main surface of the module laminate; and
at least one capacitor included in a switched-capacitor circuit and that is disposed on the second main surface of the module laminate,
wherein the at least one integrated circuit includes:
at least one switch included in the switched-capacitor circuit; and
at least one switch included in a supply modulator,
wherein the at least one capacitor included in the switched-capacitor circuit includes a first capacitor having a first electrode and a second electrode, and a second capacitor having a third electrode and a fourth electrode,
wherein the at least one switch included in the switched-capacitor circuit includes a first switch, a second switch, a third switch, a fourth switch, a fifth switch, a sixth switch, a seventh switch, and an eighth switch,
wherein:
a first end of the first switch and a first end of the third switch are connected to the first electrode,
a first end of the second switch and a first end of the fourth switch are connected to the second electrode,
a first end of the fifth switch and a first end of the seventh switch are connected to the third electrode,
a first end of the sixth switch and a first end of the eighth switch are connected to the fourth electrode,
a second end of the first switch, a second end of the second switch, a second end of the fifth switch, and a second end of the sixth switch are connected to each other,
a second end of the third switch is connected to a second end of the seventh switch,
a second end of the fourth switch is connected to a second end of the eighth switch,
wherein the supply modulator includes an output terminal,
wherein the at least one switch included in the supply modulator includes:
a ninth switch connected between the output terminal and each of the second ends of the first switch, the second switch, the fifth switch, and the sixth switch; and
a tenth switch connected between the output terminal and each of the second ends of the third switch and the seventh switch, and
wherein the at least one capacitor overlaps the at least one integrated circuit in a plan view of the module laminate.
